(19) United States
(12) Patent Application Publication
(10) Pub. No.: US 2026/0052989 A1
(43) Pub. Date: Feb. 19, 2026

(54) MECHANISMS FOR DUAL COUPLING A SEMICONDUCTOR PACKAGE ASSEMBLY TO A COMPONENT

(71) Applicant: SEMICONDUCTOR COMPONENTS INDUSTRIES, LLC, Scottsdale, AZ (US)

(72) Inventors: Seungwon IM, Bucheon (KR); Jonghwan BAEK, Seoul (KR); Dukyong LEE, Bucheon (KR); Chee Hiong CHEW, Seremban (MY); Jinseok RYU, Incheon (KR); Hyungil JEON, Namyangju-si (KR); Sangyun MA, Bucheon (KR); Hangil SHIN, Incheon (KR); Taekyun KIM, Bucheon (KR); Jihwan KIM, Seoul (KR)

(73) Assignee: SEMICONDUCTOR COMPONENTS INDUSTRIES, LLC, Scottsdale, AZ (US)

(21) Appl. No.: 19/296,854

(22) Filed: Aug. 11, 2025

Related U.S. Application Data
(60) Provisional application No. 63/683,823, filed on Aug. 16, 2024.

(51) Int. Cl. H01L 23/40; H01L 21/48; H01L 23/473; H01L 23/498; H01L 23/538; H01L 25/07

(52) U.S. Cl. CPC H01L 23/4006; H01L 21/4875; H01L 21/4878; H01L 23/473; H01L 23/49811; H01L 23/49838; H01L 23/5386; H01L 25/072; H01L 2023/405; H01L 2023/4087

(57) ABSTRACT

In a general aspect, mechanisms for dual coupling of a semiconductor package assembly to a component includes a thermal dissipation appliance; a semiconductor package assembly bonded to the thermal dissipation appliance by a thermally conductive adhesive material; and at least one clamping tool mechanically coupled to the semiconductor package assembly and to the thermal dissipation appliance, the at least one clamping tool exerting a compressive force on the semiconductor package assembly to maintain an interface between the semiconductor package assembly and the thermal dissipation appliance.

### CROSS-REFERENCE TO RELATED APPLICATIONS

This application claims the benefit of U.S. Provisional Application No. 63/683,823, filed on Aug. 16, 2024, which is hereby incorporated by reference in its entirety.

### TECHNICAL FIELD

This description relates to semiconductor package assemblies and more particularly to a mechanism for dual coupling a semiconductor package assembly to a component.

### BACKGROUND

Semiconductor package assemblies (e.g., semiconductor device power modules) may include substrates that are bonded to thermal dissipation mechanisms (e.g., heat sinks, water jackets, etc.). Mechanical stress due to thermal cycling can weaken the bond between the semiconductor package assemblies, leading to poor cooling performance and even detachment.

### SUMMARY

In a general aspect, the techniques described herein relate to an apparatus including a mechanism for dual coupling a semiconductor package assembly to a component. The apparatus includes a thermal dissipation appliance and a semiconductor package assembly bonded to the thermal dissipation appliance by a thermally conductive adhesive material. The apparatus also includes at least one clamping tool mechanically coupled to the semiconductor package assembly and to the thermal dissipation appliance. The clamping tool exerts a compressive force on the semiconductor package assembly to maintain an interface between the semiconductor package assembly and the thermal dissipation appliance.

In some implementations, the at least one clamping tool includes a screw inserted through a washer, with at least a portion of the washer being in contact with the semiconductor package assembly, and with the screw being fastened to a threaded hole in the thermal dissipation appliance. In some implementations, the screw is countersunk in the washer. In some implementations, a portion of a particular washer is seated in a recessed portion of the semiconductor package assembly. In some implementations, a top surface of the washer is substantially coplanar with a top surface of the semiconductor package assembly, the screw being countersunk in the washer. In some implementations, a surface of the recessed portion includes a groove, where the clamping tool includes a protrusion inserted into the groove.

In some implementations, the at least one clamping tool includes an L-shaped member having a first end bonded to the semiconductor package assembly and a second end bonded to the thermal dissipation appliance.

In some implementations, the thermal dissipation appliance is a cooler having a fluid cavity connected to an inlet port and an outlet port. In other implementations, the thermal dissipation appliance is a heat sink.

In some implementations, the semiconductor package assembly includes at least one semiconductor die mounted on a substrate and a molding material, wherein a bottom surface of the substrate is exposed through the molding material, the bottom surface being bonded to the thermal dissipation appliance. In some implementations, the substrate is a layered substrate including one of a direct-bonded metal substrate, an active metal brazed substrate, an aluminum substrate, and an insulated metal substrate. In some implementations, the at least one semiconductor die includes a silicon carbide device die, a silicon die, and a gallium nitride die. In some implementations, the semiconductor package assembly is sintered to the thermal dissipation appliance.

In another general aspect, the techniques described herein relate to an apparatus that includes a thermal dissipation appliance and a plurality of semiconductor package assemblies. The plurality of semiconductor package assemblies includes at least a first semiconductor package assembly, a second semiconductor package assembly, and a third semiconductor package assembly. The plurality of semiconductor package assemblies is bonded to the thermal dissipation appliance. At least one clamping tool is mechanically coupled to the plurality of semiconductor package assemblies and to the thermal dissipation appliance. The at least one clamping tool exerts a compressive force on the plurality of semiconductor package assemblies.

In some implementations, each of the plurality of semiconductor package assemblies includes at least two semiconductor power device dies receiving a direct current output and supplying a phase output of a three-phase inverter.

In some implementations, a single clamping tool is disposed across a top surface of each of the plurality of semiconductor package assemblies and mechanically coupled to the thermal dissipation appliance. In some implementations, each of the plurality of semiconductor package assemblies includes two or more recesses in a surface, where a portion of the single clamping tool is disposed in the two or more recesses.

In some implementations, each of the plurality of semiconductor package assemblies includes two or more recesses in a surface. The at least one clamping tool includes a first washer, a second washer, a third washer, and a fourth washer coupled to the thermal dissipation appliance via four or more countersunk screws. The first washer is seated in a first recess of the first semiconductor package assembly and has an L-shape. The second washer is seated in a second recess of the first semiconductor package assembly and a third recess of the second semiconductor package assembly. The second washer has a flat shape. The third washer is seated in a fourth recess of the second semiconductor package assembly and a fifth recess of the third semiconductor package assembly. The third washer has a flat shape. The fourth washer is seated in a sixth recess of the third semiconductor package assembly and has an L-shape.

In some implementations, each of the plurality of semiconductor package assemblies includes a layered substrate including a top metal layer, an insulating layer, and a bottom metal layer, where the layered substrate in one of a direct-bonded metal substrate, an active metal brazed substrate, and aluminum substrate, and an insulated metal substrate. In these implementations, the semiconductor package assembly also includes two or more semiconductor power device dies mounted on the top metal layer of the layered substrate. In these implementations, the semiconductor package assembly also includes molding material at least partially encapsulating the layered substrate, a portion of the bottom metal layer being exposed through the molding material, where the portion of the bottom metal layer is sintered to a surface of the thermal dissipation appliance.

In some implementations, at least one of the two or more semiconductor power device dies includes a silicon carbide device die, a silicon die, and a gallium nitride die.

In another general aspect, the techniques described herein relate to a method of manufacturing an assembly for dual coupling of a semiconductor package assembly to a component. The method includes disposing a thermally conductive adhesive material on a thermal dissipation appliance. The method also includes sintering at least one semiconductor package assembly to the thermal dissipation appliance. The method also includes coupling at least one clamping tool to the at least one semiconductor package assembly and to the thermal dissipation appliance. The at least one clamping tool exert a compressive force on the one or more semiconductor package assemblies.

The details of one or more implementations are set forth in the accompanying drawings and the description below. Other features will be apparent from the description and drawings, and from the claims.

### BRIEF DESCRIPTION OF THE DRAWINGS

FIG. 1 sets forth a sectional diagram of an example system for cooling a semiconductor package assembly utilizing dual coupling attachment in accordance with at least one embodiment of the present disclosure.

FIG. 2 sets forth a sectional diagram of another example system for cooling a semiconductor package assembly utilizing dual coupling attachment in accordance with at least one embodiment of the present disclosure.

FIG. 3 sets forth a sectional diagram of another example system for cooling a semiconductor package assembly utilizing dual coupling attachment in accordance with at least one embodiment of the present disclosure.

FIG. 4A sets forth a front view of an example semiconductor package assembly.

FIG. 4B sets forth a rear view of the example semiconductor package assembly of FIG. 4A.

FIG. 4C sets forth a perspective view of the example semiconductor package assembly of FIG. 4A.

FIGS. 5 and 6 sets forth an isometric diagram of an example process for fabricating a system for cooling multiple semiconductor package assemblies utilizing dual coupling attachment in accordance with at least one embodiment of the present disclosure.

FIGS. 7A and 7B set forth isometric diagrams of an example flat washer for use in dual coupling of a semiconductor package assembly to a component in accordance with at least one embodiment of the present disclosure.

FIGS. 8A and 8B set forth isometric diagrams of an example bent washer for use in dual coupling of a semiconductor package assembly to a component in accordance with at least one embodiment of the present disclosure.

FIG. 9A sets forth a top view of the example system of FIG. 6.

FIG. 9B sets forth a front view of the example system of FIG. 6.

FIG. 9C sets forth a sectional view of the example system of FIG. 6.

FIG. 9D sets forth another sectional view of the example system of FIG. 6.

FIG. 9E sets forth a detailed view of the example system of FIG. 6.

FIG. 10 sets forth a sectional diagram of another example system for cooling a semiconductor package assembly utilizing dual coupling attachment in accordance with at least one embodiment of the present disclosure.

FIGS. 11A-11C set forth an example process of fabricating the system of FIG. 10.

FIG. 12A sets forth a sectional diagram of another example system for cooling a semiconductor package assembly utilizing dual coupling attachment in accordance with at least one embodiment of the present disclosure.

FIG. 12B sets forth a detailed view of example screws for use in the system of FIG. 12A.

FIG. 13 sets forth a sectional diagram of another example system for cooling a semiconductor package assembly utilizing dual coupling attachment in accordance with at least one embodiment of the present disclosure.

FIGS. 14A-14C set forth an example process of fabricating the system of FIG. 13.

FIG. 15 sets forth a sectional diagram of another example system for cooling multiple semiconductor package assemblies utilizing dual coupling attachment in accordance with at least one embodiment of the present disclosure.

FIGS. 16A-16D set forth an example process of fabricating the system of FIG. 15.

FIG. 17 sets forth a sectional diagram of another example system for cooling multiple semiconductor package assemblies utilizing dual coupling attachment in accordance with at least one embodiment of the present disclosure.

FIGS. 18A-18C set forth an example process of fabricating the system of FIG. 17.

FIGS. 19A-19D set forth a top view of example implementations of the system of FIG. 17.

FIG. 20 sets forth a sectional diagram of another example system for cooling multiple semiconductor package assemblies utilizing dual coupling attachment in accordance with at least one embodiment of the present disclosure.

FIGS. 21A-21C set forth an example process of fabricating the system of FIG. 20.

In the various drawings, which are not necessarily drawn to scale, like reference symbols may indicate like and/or similar components (elements, structures, etc.) in different views and/or different implementations. The drawings illustrate generally, by way of example, but not by way of limitation, various implementations discussed in the present disclosure. Reference symbols shown in one drawing may not be repeated for the same, and/or similar elements in related views. Reference symbols that are repeated in multiple drawings may not be specifically discussed with respect to each of those drawings but are repeated for context and ease of cross reference between related views. Also, not all like elements in the drawings may be specifically referenced with a reference symbol when multiple instances of an element are illustrated.

### DETAILED DESCRIPTION

Modern power devices are often fabricated in a semiconductor die. These devices can deliver or switch high levels of power and can be used in power circuits for high voltage power device applications. For example, the power device applications can include high voltage applications in the range of 600 V or greater. These power devices can be included in a variety of applications including, but not limited to, automotive applications (e.g., automotive high power modules (AHPM), electrical vehicles, hybrid electrical vehicles), traction systems, solar arrays and other renewable energy systems, computer applications, industrial equipment, on-board charging applications, inverter applications, and so forth.

The power devices can be insulated gate bipolar transistors (IGBT) devices, metal oxide semiconductor field effect transistor (MOSFET) devices, silicon carbide devices, and so forth, which are fabricated in a semiconductor die. Typically, the power device dies are mounted on a substrate to form a circuit that is enclosed in a power module package. Such semiconductor device assemblies can be coupled with a thermal dissipation mechanism, appliance, device, apparatus, etc. (e.g., a heat sink, a water jacket, etc.), that can dissipate heat generated during operation of the semiconductor power device die.

Thermal dissipation appliances can transfer heat generated by the power device to, for example, a gas or liquid coolant. By transferring or directing heat away from the power devices, the temperature of the electronic components can be regulated to desirable levels. Regulating the temperature of the power devices to avoid overheating can also prevent damage to the power devices. Any overheating of or damage to the power devices can negatively impact the performance of the power devices.

When a semiconductor package is soldered or sintered to a thermal dissipation device (such as an aluminum or copper heat sink, baseplate, or cooler), thermal cycling can significantly affect the long-term reliability and mechanical integrity of the assembly. Different materials forming an interface between a package and a thermal dissipation appliance, such as the solder/sinter material and metal baseplate, have different Coefficients of Thermal Expansion (CTE). During heating and cooling, each material expands and contracts at different rates. This mismatch generates mechanical stress at the interface between the package and the thermal dissipation device. Over time, this can lead to delamination, cracking in the sinter or solder, void growth, and so on. For example, repeated expansion and contraction causes fatigue in the bonding layer (solder or sintered material). Solder may develop microcracks and sintered silver may form voids, dried-out patches, or brittle cracks. Severe stress can cause partial or total detachment of the package from the thermal dissipation appliance.

To improve high-temperature performance, embodiments of the present disclosure provide clamping tools to mechanically couple semiconductor package assemblies to a base such as a thermal dissipation appliance. The clamping tools exert a compressive force on the semiconductor package assemblies to reduce the opportunity for delamination, void growth, detachment, and stress on the bond interface between the semiconductor package assembly and the thermal dissipation appliance that may occur as a result of thermal cycling. This dual coupling approach increases the reliability, efficiency, and performance of the semiconductor device package assembly, such as a power module, by addressing and mitigating the effects of thermal cycling on the bond interface.

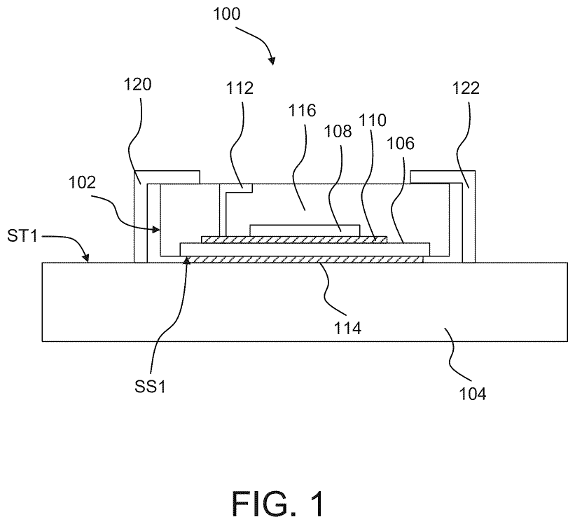

FIG. 1 illustrates an example system 100 for dual coupling of a semiconductor package assembly to a component in accordance with at least one embodiment of the present disclosure. The system 100 includes a semiconductor package assembly 102 coupled to a thermal dissipation appliance 104. In an initial stage of coupling, the semiconductor package assembly 102 is bonded to the thermal dissipation appliance 104 through a bonding processes such as, for example, a soldering or sintering process. For example, a surface SS1 of a substrate 106 of the semiconductor package assembly 102 can be bonded to a surface ST1 of the thermal dissipation appliance 104 using a thermal conductive adhesive material 114. In these implementations, such a conductive adhesive material 114 can be a solder material, a sintering material (e.g., silver or copper), an epoxy material (e.g., silver filled epoxy), or a plating material (e.g., a tin plating material). In some examples, the conductive adhesive material 114 can be a paste or a preformed sheet. In various examples, the thermal dissipation appliance can be a heat sink, a water jacket, a baseplate, a second substrate, and the like, although it should be appreciated that techniques described herein can be used to couple the semiconductor package assembly 102 to a component that is not a thermal dissipation appliance, such as a printed circuit board.

In various examples, the substrate 106 can be a ceramic substrate, a dielectric substrate, or a multi-layer substrate. In various examples, a layered substrate can include a direct-bonded metal (DBM) substrate, an active metal brazed substrate (AMB), an aluminum substrate, and an insulated metal substrate (IMS), and the like.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder. In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials. In some implementations, a coupling of components can be performed using, for example, a solder process, a sintering process (e.g., a silver sintering process, a copper sintering process), and/or other metal-to-metal type bonding processes.

The semiconductor package assembly 102 includes at least one semiconductor die 108. In some implementations, as shown in FIG. 1, at least one semiconductor die 108 is coupled to a patterned metal layer 110 on a second surface of the substrate 106 opposite the surface SS1 of the substrate. For example, the semiconductor die 108 can be coupled to the metal layer 110 by a thermally conductive adhesive 124 such as solder, thermal interface material, phase change material, sinter material, and so forth. In various examples, the semiconductor die 108 can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, the semiconductor die 108 can include a power device for conditioning, converting, or switching a power supply. In various examples, the semiconductor die 108 can implement an IGBT power electronics device, a MOSFET power electronics device, or other electronics devices suitable for controlled switching in high voltage applications. In a particular example, the semiconductor die 108 is configured as a switching device for a high voltage DC input power supply (e.g., at least 400 V). In some implementations, one or more semiconductor die can be (e.g., can be a portion of), or can include, a component for an electrical vehicle (EV). In various examples, the semiconductor die 108 can be fabricated using a silicon substrate, silicon carbide substrate, gallium nitride substrate, or a gallium arsenide.

More than one semiconductor die can be included in the implementations described herein. In some implementations, different semiconductor die (when more than one semiconductor die is included in some of the implementations) can be fabricated using different semiconductor substrates (e.g., a silicon carbide substrate, a silicon substrate, a gallium nitride substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wire bonds or clips.

In example implementations, a semiconductor package assembly (e.g., a power module) can be a hybrid device package that includes a semiconductor die or a plurality of semiconductor die that are integrated onto to a unifying electronic power substrate (e.g., a ceramic substrate, a DBM or DBC substrate, an active metal brazed (AMB) substrate). In some implementations, multiple semiconductor devices (e.g., can be fabricated on the same substrate such as a SiC substrate) suitable for high power applications.

In some implementations, as shown in FIG. 1, the semiconductor package assembly 102 includes one or more electrical interconnects 112 providing an external connection to the semiconductor package assembly. For example, the interconnects 112 can provide input or output power or control signals to and from the semiconductor package assembly 102. In various examples, the interconnects can include terminals, pins, lead frames, contacts, pads, bumps, and/or other types of interconnects that will be appreciated by those of skill in the art. The electrical interconnects 112 can be coupled to the substrate 106, for example, by solder material, sintering material, active metal brazing, and so forth to circuit elements in the patterned metal layer. In such implementations, the interconnects 112 can be directly coupled to the patterned metal layer 110 or electrically coupled to the patterned metal layer 110 or semiconductor die 108 via wire bonds, as will be appreciated by those of skill in the art. In still further implementations, the semiconductor die 108 can be coupled to a die attach paddle (not shown) on a surface of the semiconductor die opposite the substrate surface SS2, where the die attach paddle includes a lead frame.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a lead frame, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

The semiconductor package assembly 102 also includes molding material 116 encapsulating or partially encapsulating the components of the semiconductor package assembly. For example, as shown in FIG. 1, the molding material 116 encapsulates the semiconductor die 108 and a top metal layer of the substrate 106, while the molding material 116 partially encapsulates the substrate 106. The molding material 116 can be an epoxy molding compound, a resin molding compound, a gel molding compound, and so on. In some implementations, the molding material (e.g., molding material or compound, an encapsulation material) can be or can include a non-conducting layer/material. In some implementations, the molding material is a non-conducting material, such as an epoxy, which can be formed (applied, etc.) using a transfer molding process or a compression molding process. In some implementations, the molding material can include a separate plastic housing that is included in the semiconductor device assembly.

Though not specifically shown in FIG. 1, in some implementations, other elements can be included in the semiconductor package assembly 102. The specific elements included in an electronic device assembly may depend on the particular implementation.

In accordance with embodiments of the present disclosure, a mechanical retaining mechanism is employed to secure the semiconductor package assembly 102 to the thermal dissipation appliance 104. Clamping tools 120, 122 secure the semiconductor package assembly 102 to the thermal dissipation appliance 104. The clamping tools 120, 122 include a first portion mechanically coupled to the semiconductor package assembly and a second portion mechanically coupled to the thermal dissipation appliance 104. In the example shown in FIG. 1, the clamping tool is mounted on a top surface of the semiconductor package assembly 102. The clamping tools 120, 122 impart a compressive force on the top surface of the semiconductor package assembly 102 to reduce the stress on the bond between the semiconductor package assembly 102 and the thermal dissipation appliance caused by, for example, thermal cycling. The clamping tools 120, 122 can include brackets, screws, washers, nuts, bolts, edge clamps, springs, and/or other retaining mechanisms. In some examples, the clamping tools 120, 122 are composed of a metal or metal alloy. Various implementations of the clamping tools 120, 122 are set forth in more detail below. Although two clamping tools 120, 122 are shown on each side of the semiconductor package assembly 102, it will be appreciated that additional clamping tools can be used, or a single clamping tool can be used to extend across the semiconductor package assembly 102.

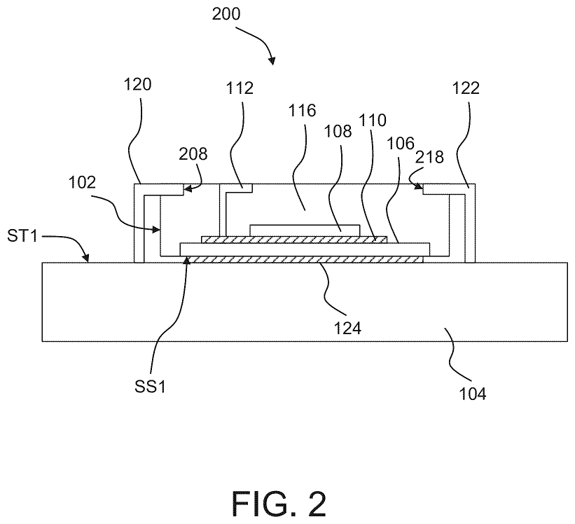

FIG. 2 sets forth a sectional view of another example system 200 for dual coupling of a semiconductor package assembly to a component in accordance with at least one embodiment of the present disclosure. The system 200 of FIG. 2 is similar to the system 100 of FIG. 1, where like numerals indicate like elements. The system 200 of FIG. 2 differs from that of FIG. 1 in that the system of FIG. 2 includes recesses 208, 218 in the top of the molding material 116. The clamping tools 120, 122 are seated in the recesses 208, 218 to limit potential movement of the semiconductor package assembly 102. The clamping tools 120, 122 include a first portion mechanically coupled to a surface of the recesses 208, 218 and a second portion mechanically coupled to the thermal dissipation appliance 104. The recesses 208, 218 can be formed in the molding material 116 by grinding, cutting, laser ablation, chemical or plasma etching, or other mechanisms for removing a portion of the molding material. In other examples, the recesses 208, 218 can be formed when the mold body is created using features of a mold tool, such as raised elements in a mold cavity whose shape is transferred to the mold body during transfer or compression molding.

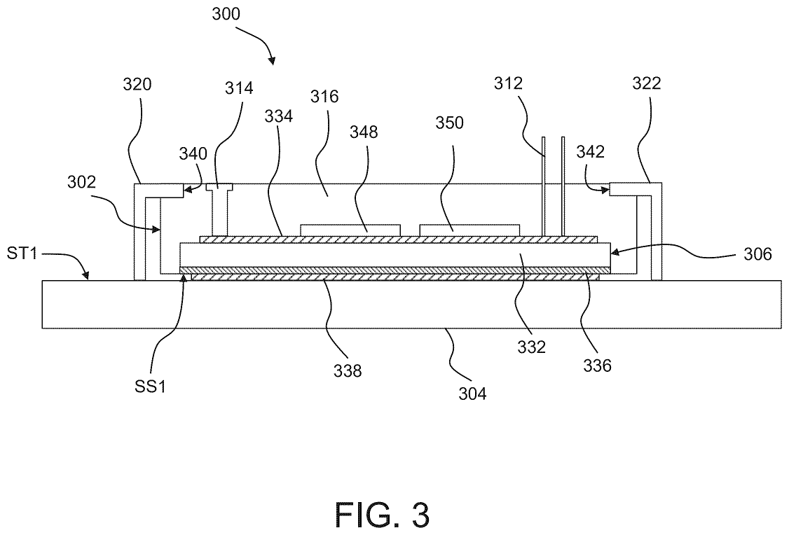

FIG. 3 sets forth a section view of another system 300 for dual coupling of a semiconductor package assembly to a component in accordance with at least one embodiment of the present disclosure. The system 300 of FIG. 3 includes a semiconductor package assembly 302 and a thermal dissipation appliance 304. The semiconductor package assembly 302 can be used to implement the semiconductor package assembly 102 of FIG. 1. The semiconductor package assembly 302 includes one or more semiconductor dies 348, 350. In some implementations, a semiconductor die 348, 350 can include a power device for conditioning, converting, or switching a power supply. In various examples, the semiconductor die 348, 350 can implement an IGBT power electronics device, a MOSFET power electronics device, or other electronics devices suitable for controlled switching in high voltage applications. In a particular example, the semiconductor die 348, 350 is configured as a switching device for a high voltage DC input power supply (e.g., at least 400 V). In various examples, the semiconductor die 348, 350 can be fabricated using silicon, silicon carbide, gallium nitride, gallium arsenide, a silicon-silicon carbide hybrid material, and other suitable semiconductor die materials that will be recognized based on the present disclosure.

At least one semiconductor die 348 is mounted on a substrate 306. In some implementations, the substrate 306 is a DBM substrate. In some implementations, the DBM substrate (e.g., direct bonded copper (DBC)) can include an insulating layer 332 disposed between a first metal layer 334 (e.g., a top metal layer) and a second metal layer 336 (e.g., a bottom metal layer). The insulating layer 332 can be, for example, a ceramic layer. In some implementations, the insulating layer 332 can be or can include, for example, a ceramic material such as alumina (Al₂O₃) or aluminum nitride (AlN)). In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process (e.g., diffusion bonding).

In some implementations, the first metal layer 334 of the DBM substrate 306 can be or can include a patterned metal layer including one or more electrically conductive traces. In some implementations, the first metal layer 334 can be or can include a patterned layer configured to form one or more electrical circuits, one or more conductive blind and/or through vias, and/or so forth. In some examples, the first metal layer 334 includes one or more circuit portions, contacts, pads, and so forth.

In the example of FIG. 3, a bottom surface of the bottom metal layer 336 of the substrate 306 corresponds to a surface SS1 of the substrate 306 that is coupled to the thermal dissipation appliance 304 via a thermally conductive adhesive material 338 via a bonding process such as, for example, soldering or sintering. In these implementations, the conductive adhesive material 338 can be a solder material, a sintering material (e.g., silver or copper), an epoxy material (e.g., silver filled epoxy), a thermal interface material, and so forth.

In some implementations, as shown in FIG. 3, the semiconductor package assembly 302 includes one or more signal pins 312 extending in a direction orthogonal to the patterned first metal layer 334 on top surface of the substrate 306. In some examples, the signal pins 312 can be inserted (e.g., press-fit) into the substrate 306. For example, the signal pins 312 can be press-fit into plated openings in the substrate 306, where the plated openings can be electrically connected with respective portions of the patterned first metal layer 334 of the substrate 306. The signal pins 312 provide an external electrical interconnect for the semiconductor package assembly 302.

In some implementations, the semiconductor package assembly 302 includes one or more input power terminals 314 provide an external electrical interconnect for the semiconductor package assembly 302 to receive an input power supply, such as a DC power supply. For example, the input power terminals may be located on a top surface of the semiconductor package assembly 302. In these implementations, the semiconductor package assembly 302 also includes one or more output power terminals (not shown) extending from the semiconductor package assembly 302, for example, in a direction parallel to the substrate 306. For example, the power terminals 314 provide an electrical connection for power output from the semiconductor package assembly 302. In such implementations, the semiconductor package assembly 302 can provide power regulation, switching, phase inversion, and other power control or conditioning functions.

In some implementations, the semiconductor package assembly includes a second semiconductor die 350 mounted on the substrate 306. The semiconductor die 348 and the semiconductor die 350 are power switching devices arranged as a half bridge circuit providing high side switching and low side switching.

The semiconductor package assembly 302 also includes molding material 316 encapsulating or partially encapsulating the components of the semiconductor package assembly 302. For example, as shown in FIG. 3, the molding material 316 encapsulates the semiconductor die 348 and metal layer 334 of the substrate 306, while the molding material 316 partially encapsulates the substrate 306, the signal pins 312, and the power terminals 314. The bottom metal layer 336 (surface SS1) of the substrate 306 is exposed through the molding material 316, while the signal pins 312 extend through the molding material 316. The molding material 316 can be an epoxy molding compound, a resin molding compound, a gel molding compound, and so on. Though not specifically shown in FIG. 3, in some implementations, other elements can be included in the semiconductor package assembly 302.

In an initial stage of coupling, the semiconductor package assembly 302 is bonded to the thermal dissipation appliance 304, where the bottom metal layer 336 is bonded to a surface ST1 of the thermal dissipation appliance 304. In some implementations, the bottom metal layer 336 and the thermal dissipation appliance 304 are bonded using a thermal conductive adhesive material 338. In these implementations, such a conductive adhesive material can be a solder material, a sintering material (e.g., silver or copper), an epoxy material (e.g., silver filled epoxy), or a plating material (e.g., a tin plating material). In various examples, the thermal dissipation appliance 304 can be a heat sink, a water jacket, a second substrate, and the like, although it should be appreciated that techniques described herein can be used to couple the semiconductor package assembly 302 to a component that is not a thermal dissipation appliance, such as a printed circuit board, chassis, baseplate, second substrate, and so forth.

In the example of FIG. 3, the semiconductor package assembly 302 includes recesses 340, 342 in the top surface and sides of the molding material 316. Clamping tools 320, 322 are seated in the recesses 340, 342 to limit potential movement of the semiconductor package assembly 302. The clamping tools 320, 322 include a first portion mechanically coupled to a surface of the recesses 340, 342 and a second portion mechanically coupled to the thermal dissipation appliance 304. The clamping tools 320, 322 impart a compressive force on the semiconductor package assembly 302 to reduce the stress on the bond between the semiconductor package assembly 302 and the thermal dissipation appliance 304 caused by, for example, thermal cycling. The clamping tools 320, 322 can include brackets, screws, washers, nuts, bolts, edge clamps, springs, and other retaining mechanism. In some examples, the clamping tools 320, 322 are composed of a metal or metal alloy. Various implementations of the clamping tools 320, 322 are set forth in more detail below. Although two clamping tools 320, 322 are shown on each side of the semiconductor package assembly 302, it will be appreciated that additional clamping tools can be used, or a single clamping tool can be used to extend across the semiconductor package assembly 302.

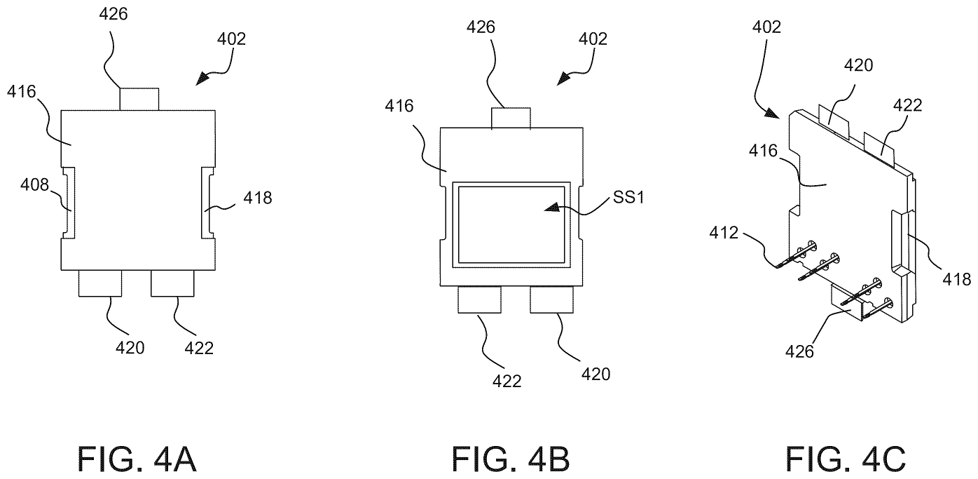

For further illustration, FIGS. 4A to 4C illustrate an external view of an example semiconductor package assembly 402 that can implement the semiconductor package assembly 102 of FIGS. 1 and 2 and/or the semiconductor package assembly 302 of FIG. 3. In some examples, the semiconductor package assembly 402 is a power module that includes a power electronics die such as, for example, an IGBT device die or a MOSFET device die. FIG. 4A is a front view of the semiconductor package assembly 402 showing a top surface of molding material 416 as well as input power terminals 420, 422 and an output power terminal 426. For example, the input power terminals 420, 422 can correspond to the input power terminal 314 of FIG. 3. The molding material 416 can correspond to the molding material 116 of FIG. 1 or the molding material 316 of FIG. 3. FIG. 4B is a rear view of the semiconductor package assembly 402 showing an exposed surfaces SS1 of an embedded substrate. For example, the surface SS1 can be a bottom surface of the bottom metal layer 336 of substrate 306 in FIG. 3. FIG. 4C is a perspective view of the semiconductor package assembly 402 showing signal pins 412 protruding through the molding material 416. For example, the signal pins 412 can correspond to the signal pins 312 of FIG. 3. FIGS. 4A and 4C illustrate recesses 408, 418 in the molding material 416 of the semiconductor package assembly 402. The recesses 408, 418 can correspond to the recesses 208, 218 in FIG. 2 and/or the recesses 340, 342 in FIG. 3.

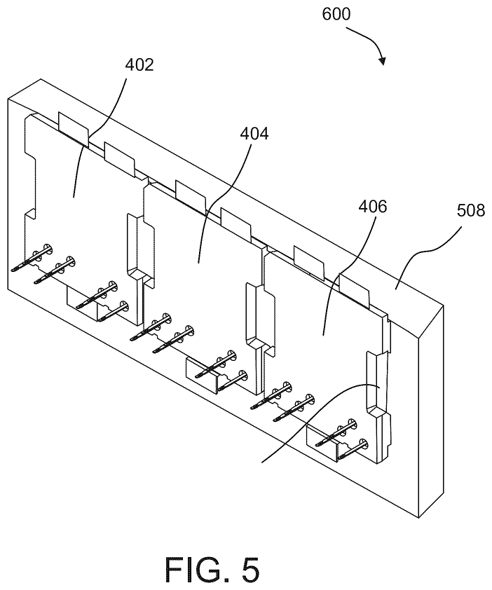

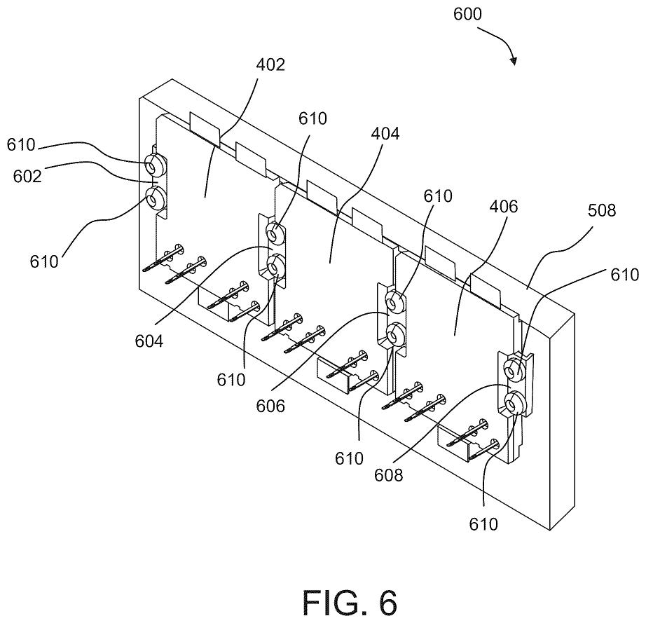

For further illustration, FIGS. 5 and 6 show an example process for constructing a system utilizing dual coupling of a semiconductor package assembly to a component in accordance with at least one embodiment of the present disclosure. FIG. 5 is a perspective view of an example implementation in which the semiconductor package assemblies 402 of FIGS. 4A-4C and two other semiconductor package assemblies 404, 406 are coupled to a thermal dissipation appliance. It will be appreciated that more or fewer semiconductor package assemblies can be coupled to the thermal dissipation appliance. In the example of FIG. 5, the thermal dissipation appliance is a water jacket 508.

In some implementations, the semiconductor package assemblies 402, 404, 406 are power modules. As such, in these implementations, the semiconductor package assemblies 402, 404, 406 can form a three-phase inverter with each semiconductor package assembly 402, 404, 406 providing a phase of a three-phase output. To generate the three-phase output, each phase can be driven by a half-bridge circuit comprising at least two power switching devices in each semiconductor package assembly 402, 404, 406, with each phase utilizing a high-side and a low-side switch to produce the corresponding phase voltage.

In some examples, the semiconductor package assemblies 402, 404, 406 are coupled to a cover or surface of the water jacket 508. For example, the semiconductor package assemblies 402, 404, 406 can be coupled to the water jacket 508 via a solder paste (e.g., silver paste), and a sintering process is used to bond the semiconductor package assemblies 402, 404, 406 to the water jacket 508. In some examples, the water jacket 508 is composed of aluminum or an aluminum alloy.

FIG. 6 is a perspective view of a system 600 in which, during a second phase of coupling, the semiconductor package assemblies 402, 404, 406 are coupled to the water jacket 508 via clamping tools as discussed above. In the example of FIG. 6, the clamping tools are washers 602, 604, 606, 608 and screws 610. For example, each washer 602, 604, 606, 608 can include one or more through holes (not visible in the view) into which a screw 610 is inserted. The screw 610 passes through the through hole of the washer and fastens into a threaded hole (not visible in the view) in the surface of the water jacket 508. The washers 602, 604, 606, 608 are seated in recesses (e.g., recesses 408, 418) of the semiconductor package assemblies 402, 404, 406 and exert a compressive force on the semiconductor package assemblies 402, 404, 406 via mechanical coupling of the screws 610 to the water jacket 508.

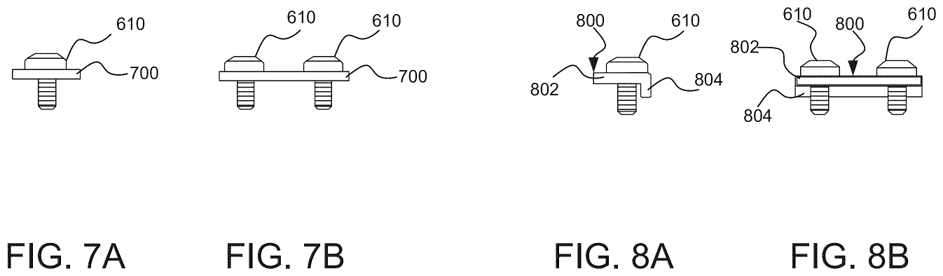

In some implementations, at least two types of washers can be used. FIGS. 7A and 7B illustrate a flat washer 700, where FIG. 7A is a top view and FIG. 7B is a side view. The flat washer 700 can be used to clamp two semiconductor package assemblies and are thus dual clamping washers. For example, in FIG. 6, a first side of the flat washer 700 can be seated in the recesses 408, 418 of two semiconductor package assemblies. A screw 610 is inserted into a through hole in the washer 700. FIGS. 8A and 8B illustrate a bent washer 800, where FIG. 8A is a top view and FIG. 8B is a side view. The bent washer 800 includes a top portion 802 and a side portion 804 that is orthogonal to the top portion 802 and extending from the top portion 802. The bent washer 800 can be used to clamp a single semiconductor package assembly. A first end of the bent washer 800 on the top portion 802 can be seated in a recess 408, 418 of a semiconductor package assembly, while a second end of the bent washer 800 on the side portion 804 can be seated against the surface of the water jacket 508 after assembly. A screw 610 is inserted into a through hole in the washer 800.

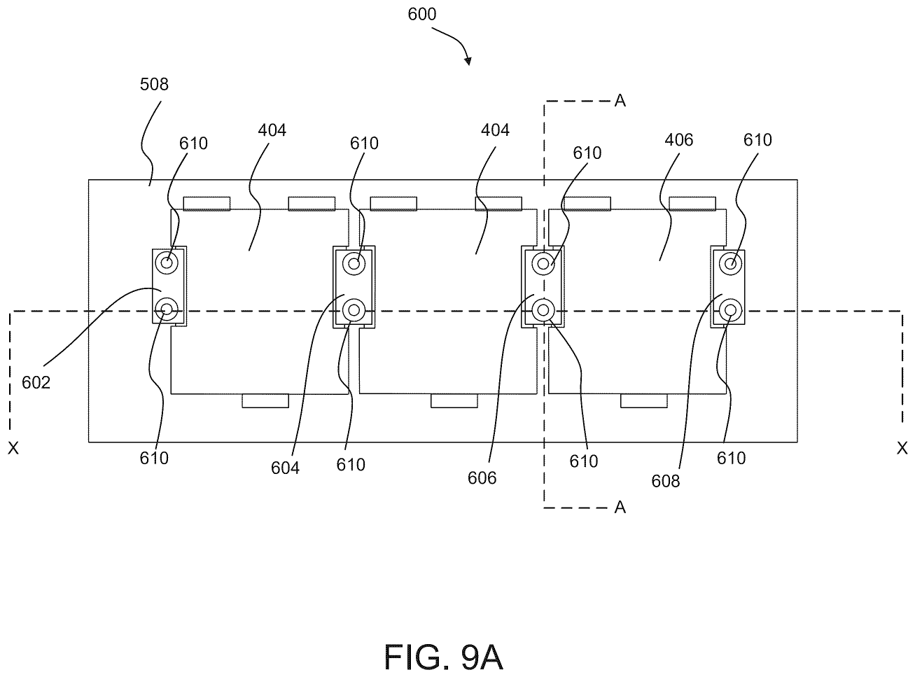

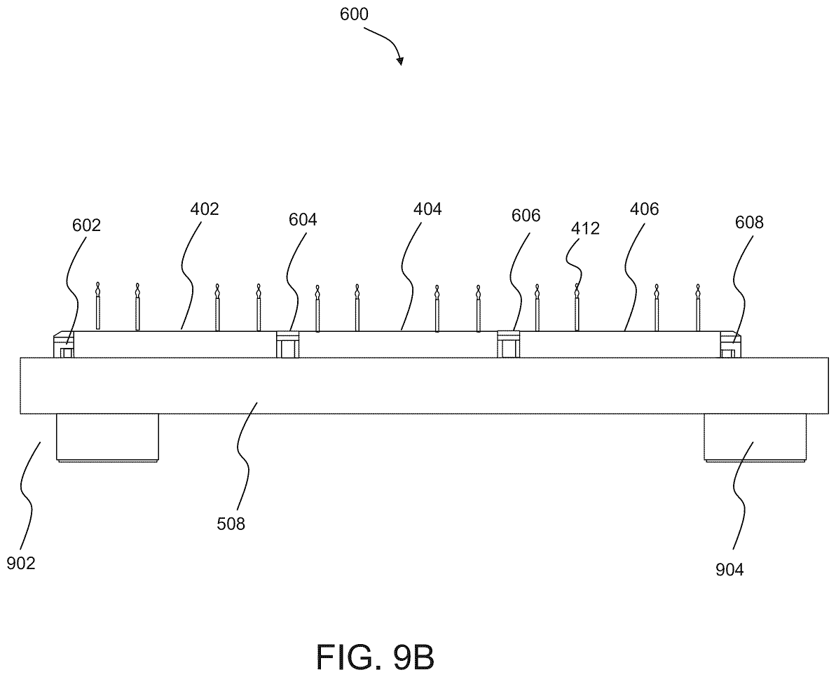

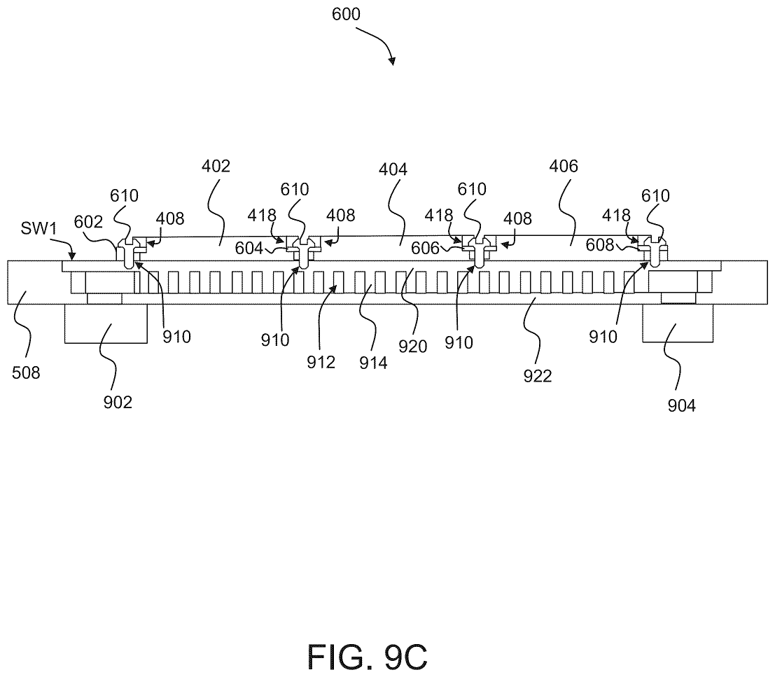

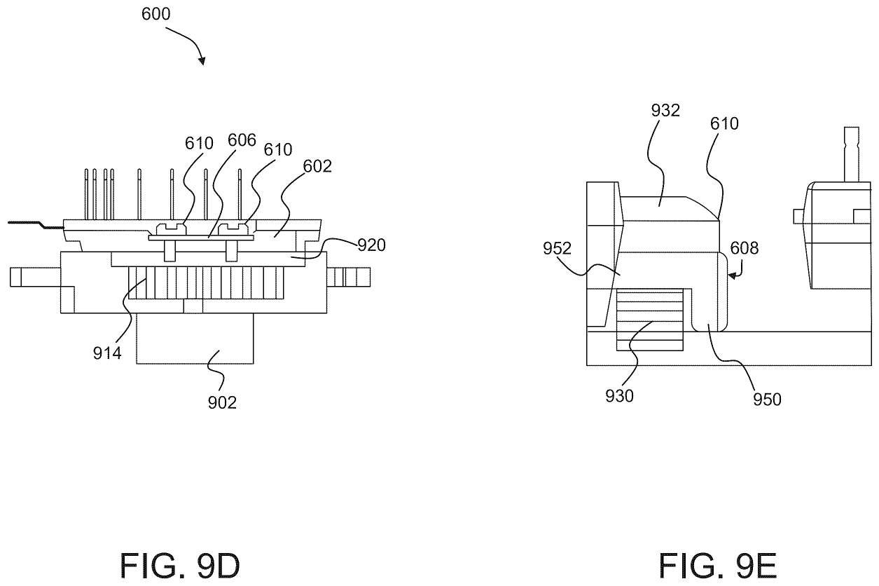

For further illustration, FIGS. 9A-9E set forth additional views of the system 600 in FIG. 6, where like numerals represent like elements. FIG. 9A is a top view of the system 600. FIG. 9B is a front view of the system 600. In some examples, the water jacket 508 includes an inlet port 902 and an outlet port 904 coupled to a fluid channel within the water jacket 508. A heat transfer medium can be pumped through the fluid channel to cool the semiconductor package assemblies 402, 404, 406. In some implementations, the fluid channel includes cooling fins.

FIG. 9C is a sectional view of system 600 taken along line X-X in FIG. 9A. FIG. 9D is a sectional view taken along line A-A in FIG. 9A. In FIGS. 9C and 9D, washers 602, 608 are bent washers, such as bent washer 800 in FIGS. 8A and 8B. Washers 604, 606 are flat washers, such as flat washers 700 in FIGS. 7A and 7B. Screws 610 are inserted into through holes in the washers 602, 604, 606, 608 and fastened into threaded holes 910 in the surface SW1 of the water jacket 508, thus clamping the semiconductor package assemblies 402, 404, 406 onto the water jacket 508. In the example of FIGS. 9C and 9D, washer 602 is seated in recess 408 of semiconductor package assembly 402. Washer 602 is a bent washer like washer 800 and is secured against surface SW1 of the water jacket 508 via a screw 610 fastened into a threaded hole 910. Washer 604 is seated in recess 418 of semiconductor package assembly 402 and recess 408 of semiconductor package assembly 404. Washer 604 is a flat washer like washer 700 and coupled to surface SW1 of the water jacket 508 via a screw 610 fastened into a threaded hole 910. Washer 606 is seated in recess 418 of semiconductor package assembly 404 and recess 408 of semiconductor package assembly 406. Washer 606 is a flat washer like washer 700 and is coupled to surface SW1 of the water jacket 508 via a screw 610 fastened into a threaded hole 910. Washer 608 is seated in recess 408 of semiconductor package assembly 406. Washer 608 is a bent washer like washer 800 and is secured against surface SW1 of the water jacket 508 via a screw 610 fastened into a threaded hole 910.

In some implementations, the water jacket 508 includes a cover 920 that provides the surface SW1 of the water jacket to which the semiconductor package assemblies 402, 404, 406 are bonded. The water jacket 508 also includes a base 922 to which the cover 920 is attached. The cover 920 and the base 922 define, at least in part, a fluid channel 912 connecting the inlet port 902 to the outlet port 904. In the examples of FIGS. 9C and 9D, cooling fins 914 (e.g., pin fins) are disposed within the fluid channel 912 to facilitate cooling. In some examples, the cooling fins 914 extend from an interior surface of the cover 920 (opposite SW1) into the fluid channel 912 to facilitate cooling of the semiconductor package assemblies 402, 404, 406.

FIG. 9E is a detailed view of washer 608, where a first end 952 of the bent washer 608 on the top portion 802 can be seated in a recess 418 of semiconductor package assembly 406, while a second end 950 of the bent washer 608 on the side portion 804 is seated against the surface SW1 of the water jacket 508. The screw 610 includes a head 932 and a threaded portion 930 that is fastened into a threaded hole 910 of the water jacket 508

In various implementations, the washers 602, 604, 606, 608 can be metal washers and the screws 610 can be metal screws. In various implementations, the washers 602, 604, 606, 608 can be plastic washers and the screws 610 can be plastic screws. In various implementations, the washers 602, 604, 606, 608 can be coated metal washers and screws 610 can be coated metal screws. In some examples, the heads of the screws 610 are flat heads and are countersunk in the washers 602, 604, 606, 608. For example, the through holes in the washers can include a conical recess to accommodate an angled or tapered head of a flat head screw.

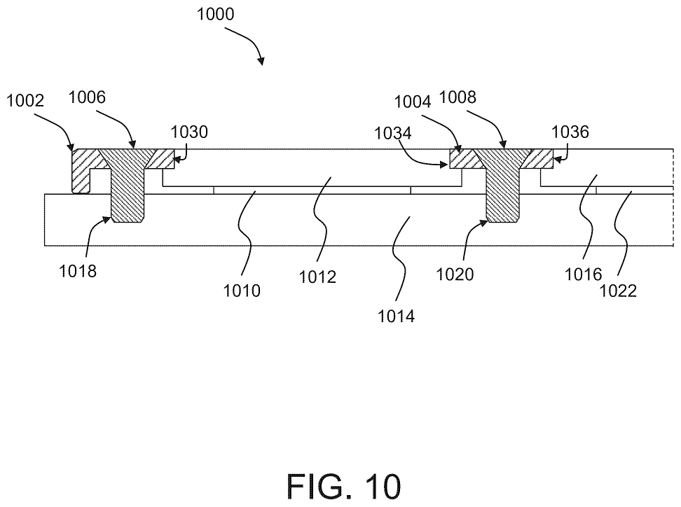

FIG. 10 sets forth a sectional view of a system 1000, shown in part, that employs countersunk screws. A package 1012 is bonded to a base 1014 via coupling material 1010, such as solder or sinter material. The package 1012 can implement the semiconductor package assembly 102 of FIG. 1 or 2 or the semiconductor package assembly 302 of FIG. 3. The base 1014 can be part of a thermal dissipation appliance such as a water jacket or heat sink. A washer 1002 is seated in a recess 1030 of a package 1012. A countersunk screw 1006 is inserted through the washer 1002 and fastened into a threaded hole 1018 in a base 1014 (e.g., a cover of a water jacket). The washer 1002 includes a conical-shaped through hole into which a conical-shaped screw head is received. This allows the top surface of the washer 1002 and the top surface of the screw 1006 to be substantially coplanar with a top surface of the package 1012.

In the example system 1000 of FIG. 10, package 1016 is bonded to the base 1014 via coupling material 1022. For example, the coupling material 1312 can be solder, sinter material, thermal interface material, or another thermally conductive adhesive material. A washer 1004 is seated in a recess 1034 of package 1012 and in a recess 1036 of package 1016. A countersunk screw 1008 is inserted through washer 1004 and fastened into a threaded hole 1020 in the base 1014. The washer 1004 includes a conical-shaped through hole into which a conical-shaped screw head of screw 1008 is received. This allows the top surface of the washer 1004 and the top surface of the screw 1008 to be substantially coplanar with a top surface of the package 1012 and the top surface of package 1016.

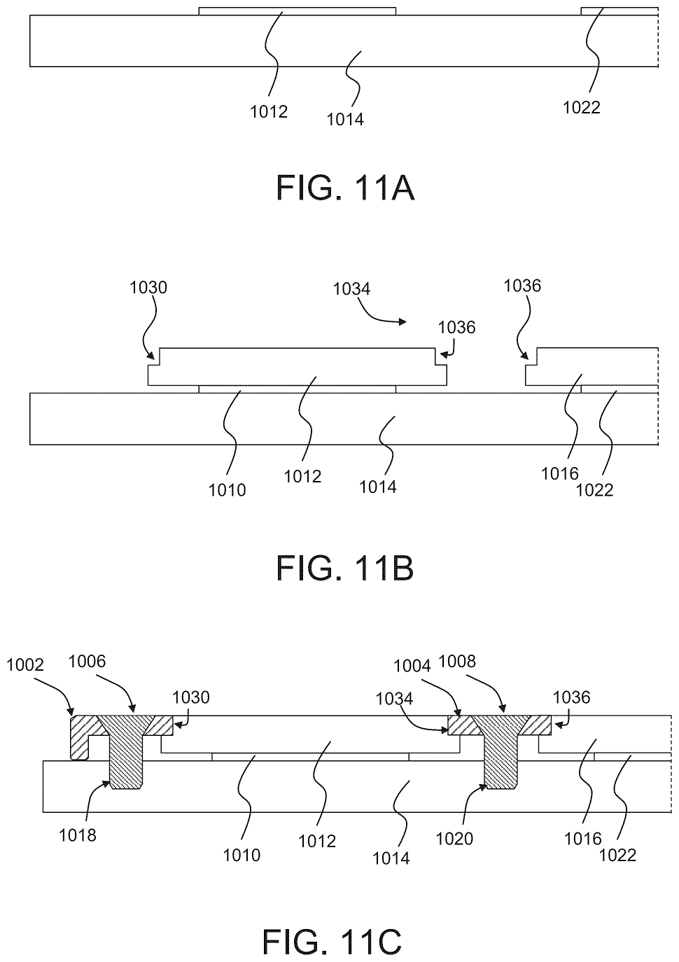

FIGS. 11A to 11C set forth a method of fabricating the system of FIG. 10, where the same reference numerals are continued. As shown in FIG. 11A, coupling material 1010, 1022 is deposited on the base 1014. The coupling material 1010, 1022 can be a conductive adhesive such as solder or sinter material. For example, the coupling material can be a film or sheet of metal sinter material such as, for example, a silver paste. In FIG. 11B, packages 1012, 1016 are mounted on the coupling material 1010, 1022 and a bonding process is carried out, such as reflow, sintering, or brazing. In a sintering process, a sintering tool applies mechanical pressure to the packages 1012, 1016 while the system is heated to, for example, 200 to 250 degrees Celsius.

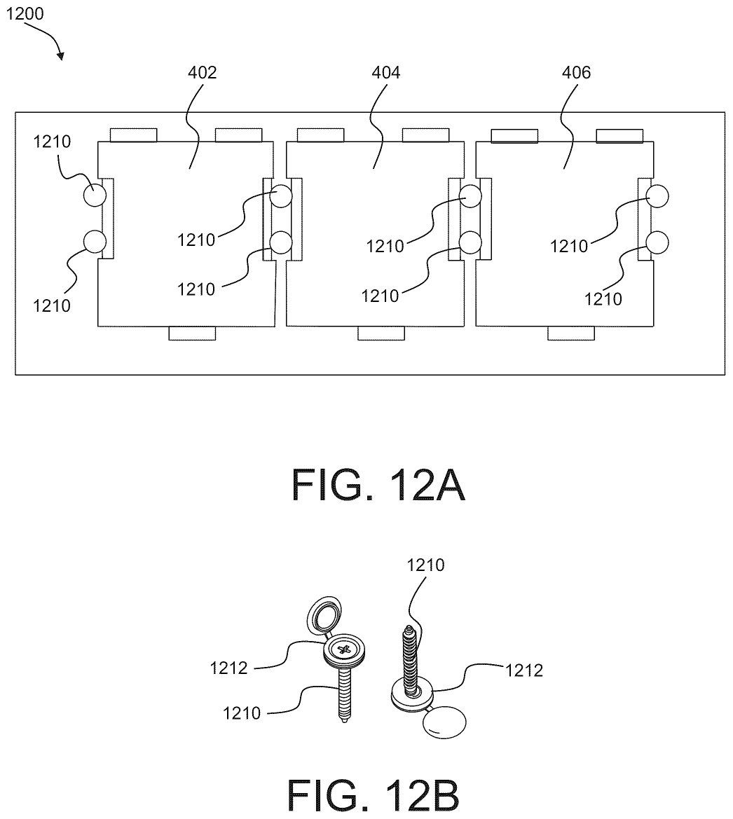

FIGS. 12A and 12B illustrate another example system 1200 for semiconductor package assemblies in accordance with at least one embodiment of the present disclosure. The system 1200 is similar to the system 600 discussed above. However, system 1200 does not utilize washers. FIG. 12A is a top view of the system 1200 while FIG. 12B illustrates a screw 1210 having a plastic cap 1212 that can be used as the retaining clamp discussed above. In the example system 1200, the plastic cap 1212 is seated in the recesses 408, 418 of the semiconductor package assemblies 402, 404, 406. The screws 1210 are fasted into threaded holes in the surface of the water jacket 508 to exert a compressive force on the semiconductor package assemblies 402, 404, 406 through mechanical coupling of the screws 1210 to the water jacket 508.

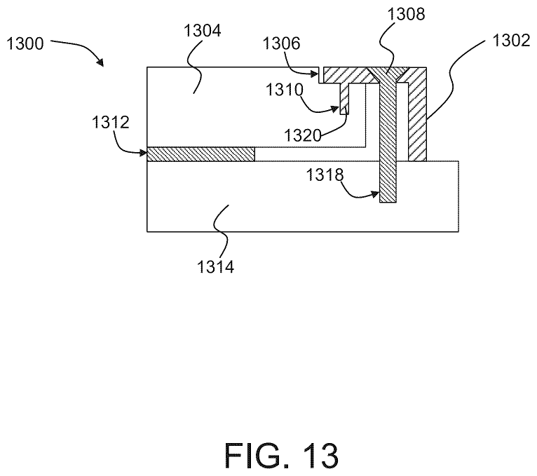

FIG. 13 sets forth a sectional view of a system 1300 for dual coupling of a semiconductor package assembly to a component in accordance with at least one embodiment of the present disclosure, where the system 1300 employs countersunk screws. A package 1304 is bonded to a base 1314 via coupling material 1312 (only a section of the package 1304 is shown in FIG. 13). The coupling material 1312 can be solder, sinter material, thermal interface material, or another thermally conductive adhesive material. The package 1304 can implement the semiconductor package assembly 102 of FIG. 1 or 2 or the semiconductor package assembly 302 of FIG. 3. The base 1314 can be part of a thermal dissipation appliance such as a water jacket or heat sink. A clamping tool 1302 is seated in a recess 1306 of a package 1304. A countersunk screw 1308 is inserted through the clamping tool 1302 and fastened into a threaded hole 1318 in the base 1314). The clamping tool 1302 includes a conical-shaped through hole into which a conical-shaped screw head is received. This allows the top surface of the clamping tool 1302 and the top surface of the screw 1308 to be substantially coplanar with a top surface of the package 1304.

In the example of FIG. 13, the recess 1306 of the package 1304 includes a groove 1310. A protrusion 1320 of the clamping tool 1302 is inserted into the groove 1310. This arrangement further limits the movement of the package 1304. The groove 1310 can be implemented in various arrangements. In one example, a single long groove in the recess is utilized. In another example, a pattern of multiple grooves 1310 can be used. In some examples, the grooves 1310 are rectangular. In other examples, multiple circular holes in the molding can be used to implement the groove 1310.

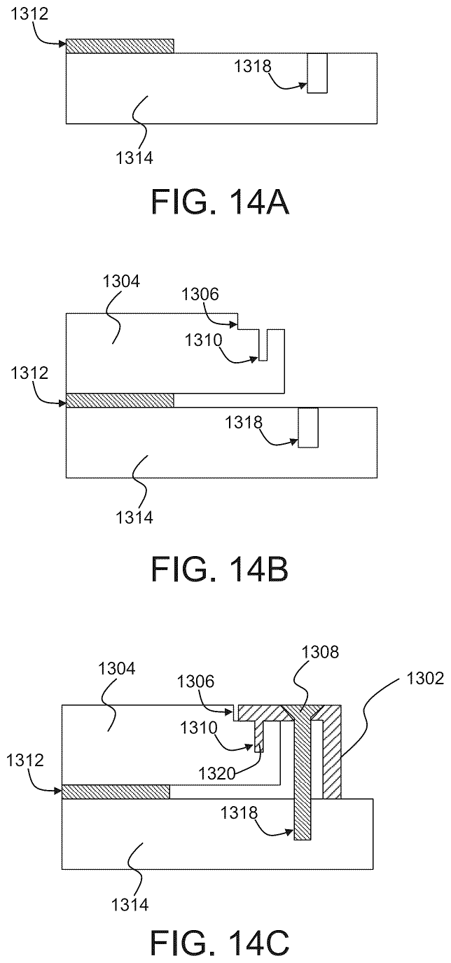

FIGS. 14A to 14C set forth a method of fabricating the system of FIG. 10, where the same reference numerals are continued. As shown in FIG. 14A, coupling material 1312 is deposited on the base 1314. The coupling material 1312 can be a conductive adhesive such as solder or sinter material. For example, the coupling material can be a film or sheet of metal sinter material such as, for example, a silver paste. In FIG. 14B, package 1304 is mounted on the coupling material 1312 and a bonding process is carried out, such as reflow, sintering, or brazing. In a sintering process, a sintering tool applies mechanical pressure to the package 1304 while the system is heated to, for example, 200 to 250 degrees Celsius. It will be appreciated that the package 1304 includes a recess 1306 and a groove 1310 in the recess 1306. In FIG. 14C, the clamping tool 1302 is seated on the recess 1306 such that a protrusion 1320 of the clamping tool 1302 is inserted into the groove 1310. The screw 1308 is inserted through the clamping tool 1302 and fastened into a threaded hole 1318 on the base 1314 to mechanically couple the clamping tool to the base 1314.

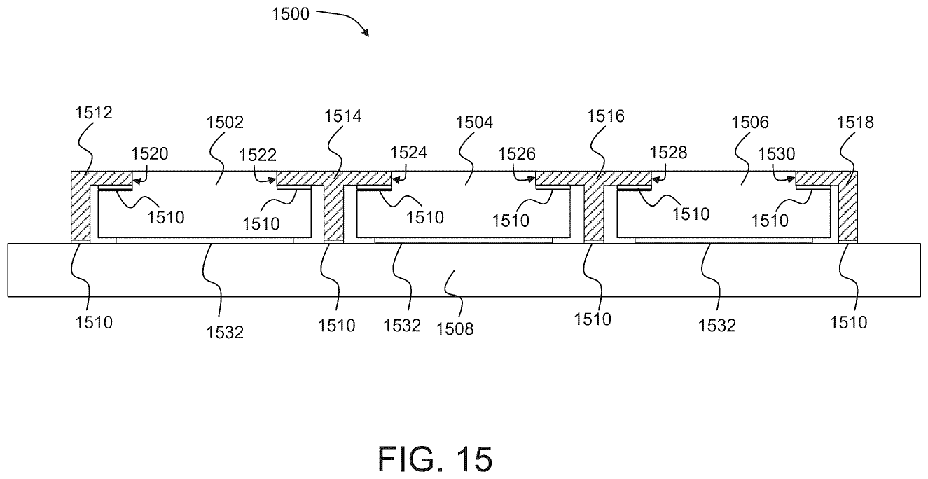

FIG. 15 sets forth another example system 1500 for dual coupling of a semiconductor package assembly in accordance with at least one embodiment of the present disclosure. In the example of FIG. 15, semiconductor package assemblies 1502, 1504, 1506 are coupled to a base 1508 via coupling material 1532. For example, the coupling material can be solder, sinter material, thermal interface material, or another thermally conductive adhesive material. In a particular implementation, the semiconductor package assemblies 1502, 1504, 1506 are sintered onto the base 1508. In some implementation, the base 1508 is a thermal dissipation appliance such as a heat sink or water jacket. The semiconductor package assemblies 1502, 1504, 1506 can implement the semiconductor package assembly 102 of FIG. 1 or 2 or the semiconductor package assembly 302 of FIG. 3, or similar devices. In a particular implementation, the semiconductor package assemblies 1502, 1504, 1506 are power modules, as discussed above.

A clamping tool 1512 is seated in a recess 1520 of semiconductor package assembly 1502 and bonded to a surface of the recess 1520 via an adhesive material 1510. For example, the adhesive material 1510 can be an epoxy, resin, solder, thermal interface material, phase change material, or sinter material, and so forth. The other end of the clamping tool 1512 is bonded to a surface of the base 1508 via the adhesive material 1511. The adhesive material 1511 can be an epoxy, resin, solder, thermal interface material, phase change material, sinter material, and so forth. The adhesive material 1510 and the adhesive material 1511 can be the same or different materials. In some examples, as shown in FIG. 15, the clamping tool is an L-shaped bracket.

A clamping tool 1514 is seated in a recess 1522 of semiconductor package assembly 1502 and a recess 1524 of semiconductor package assembly 1504, and bonded to a surface of the recess 1522 and a surface of the recess 1524 via the adhesive material 1510. A bottom end of the clamping tool 1514 is bonded to a surface of the base 1508 via the adhesive material 1511. In some examples, as shown in FIG. 15, the clamping tool 1514 is a T-shaped bracket. However, other shapes are contemplated, such as a V-shape. The clamping tool 1512 and the clamping tool 1514 exert a compressive force on semiconductor package assembly 1502 to reduce the stress on the bond between the semiconductor package assembly 1502 and the base 1508 caused by, for example, thermal cycling.

A clamping tool 1516 is seated in a recess 1526 of semiconductor package assembly 1504 and a recess 1528 of semiconductor package assembly 1506, and bonded to a surface of the recess 1526 and a surface of the recess 1528 via the adhesive material 1510. A bottom end of the clamping tool 1516 is bonded to a surface of the base 1508 via the adhesive material 1511. In some examples, as shown in FIG. 15, the clamping tool 1516 is a T-shaped bracket. However, other shapes are contemplated. The clamping tool 1514 and the clamping tool 1516 exert a compressive force on semiconductor package assembly 1504 to reduce the stress on the bond between the semiconductor package assembly 1504 and the base 1508 caused by, for example, thermal cycling.

A clamping tool 1516 is seated in a recess 1530 of semiconductor package assembly 1506 and bonded to a surface of the recess 1530 via an adhesive material 1510. The other end of the clamping tool 1518 is bonded to a surface of the base 1508 via the adhesive material 1511. In some examples, as shown in FIG. 15, the clamping tool is an L-shaped bracket. The clamping tool 1516 and the clamping tool 1518 exert a compressive force on semiconductor package assembly 1506 to reduce the stress on the bond between the semiconductor package assembly 1506 and the base 1508 caused by, for example, thermal cycling.

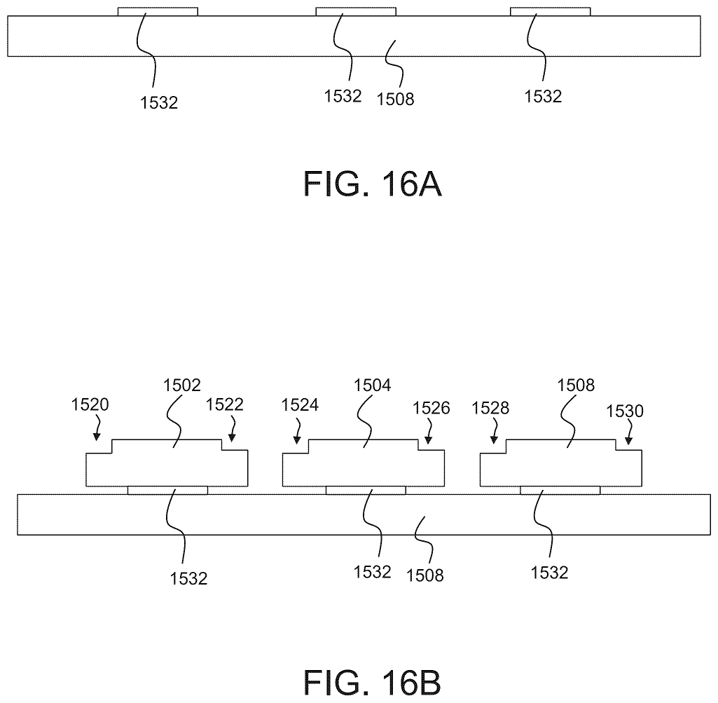

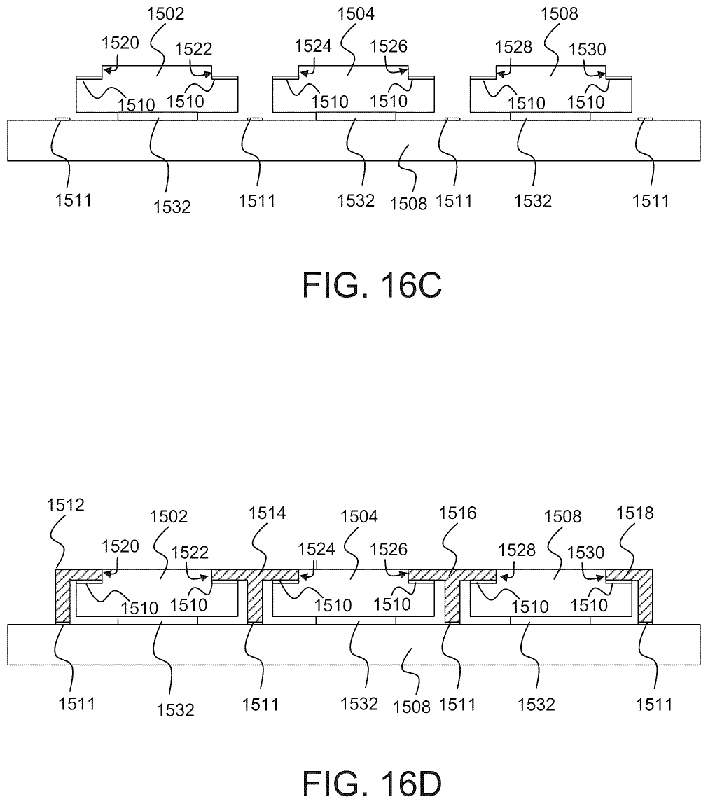

FIGS. 16A-16D set forth an example process for fabricating the system 1500 of FIG. 15. In FIG. 16A, the coupling material 1532 is deposited on the base 1508. In one example, the coupling material is a film of sinter paste (e.g., silver sinter paste). In FIG. 16B, the semiconductor package assemblies 1502, 1504, 1506 are disposed on the coupling material and a bonding process is carried out, such as reflow, sintering, brazing, or other processes. In FIG. 16C, the adhesive material 1510, 1511 is applied to the semiconductor package assemblies 1502, 1504, 1506 and to the base 1508. Alternatively, the adhesive material 1510, 1511 can be pre-applied to the clamping tools 1512, 1514, 1516, 1518. In FIG. 16D, the clamping tools 1512, 1514, 1516, 1518 are affixed to the semiconductor package assemblies 1502, 1504, 1506 and to the base 1508 via the adhesive material 1510, 1511. In an alternative implementation, where sinter material is used as the adhesive material 1510, 1511 and the coupling material 1532, the semiconductor package assemblies 1502, 1504, 1506 can be sintered to the base 1508 at the same time the clamping tools 1512, 1514, 1516, 1518 are sintered to the semiconductor package assemblies 1502, 1504, 1506.

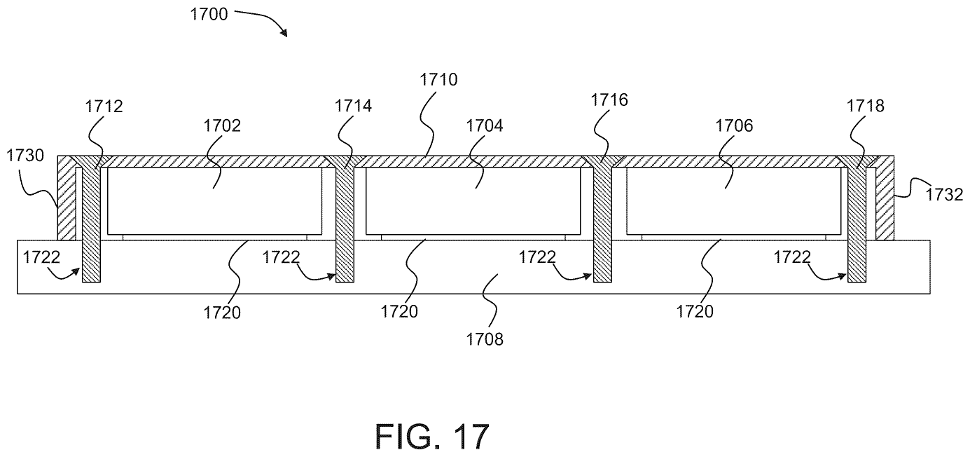

FIG. 17 sets forth another example system 1700 for dual coupling of a semiconductor package assembly in accordance with at least one embodiment of the present disclosure. In the example of FIG. 17, semiconductor package assemblies 1702, 1704, 1706 are coupled to a base 1708 via coupling material 1720. For example, the coupling material 1720 can be a thermally conductive adhesive such as solder or sinter material. In a particular implementation, the semiconductor package assemblies 1702, 1704, 1706 are sintered onto the base 1708. In some implementation, the base 1708 is a thermal dissipation appliance such as a heat sink or water jacket. The semiconductor package assemblies 1702, 1704, 1706 can implement the semiconductor package assembly 102 of FIG. 1 or 2 or the semiconductor package assembly 302 of FIG. 3, or similar devices. In a particular implementation, the semiconductor package assemblies 1702, 1704, 1706 are power modules, as discussed above.

A clamping tool 1710 is disposed across the top surfaces of the semiconductor package assemblies 1702, 1704, 1706. In some implementations, the clamping tool 1710 includes two or more sidewalls 1730, 1732 that extend downward toward a surface of the base 1708. The sidewalls 1730, 1732 can serve to offset the clamping tool from the base 1708 and prevent over-clamping. The clamping tool 1710 is coupled to the base 1708 by screws 1712, 1714, 1716, 1718. In some implementations, the screws 1712, 1714, 1716, 1718 are countersunk screws that are inserted through the clamping tool 1710 and fastened into a threaded hole 1722 in the base 1708. In these implementations, the clamping tool 1710 includes a conical-shaped through hole into which a conical-shaped screw head is received. This allows the top surfaces of the screws 1712, 1714, 1716, 1718 to be substantially coplanar with a top surface of the clamping tool 1710. The clamping tool 1710 exerts a compressive force on semiconductor package assemblies 1702, 1704, 1706 to reduce the stress on the bond between the semiconductor package assemblies 1702, 1704, 1706 and the base 1708 caused by, for example, thermal cycling.

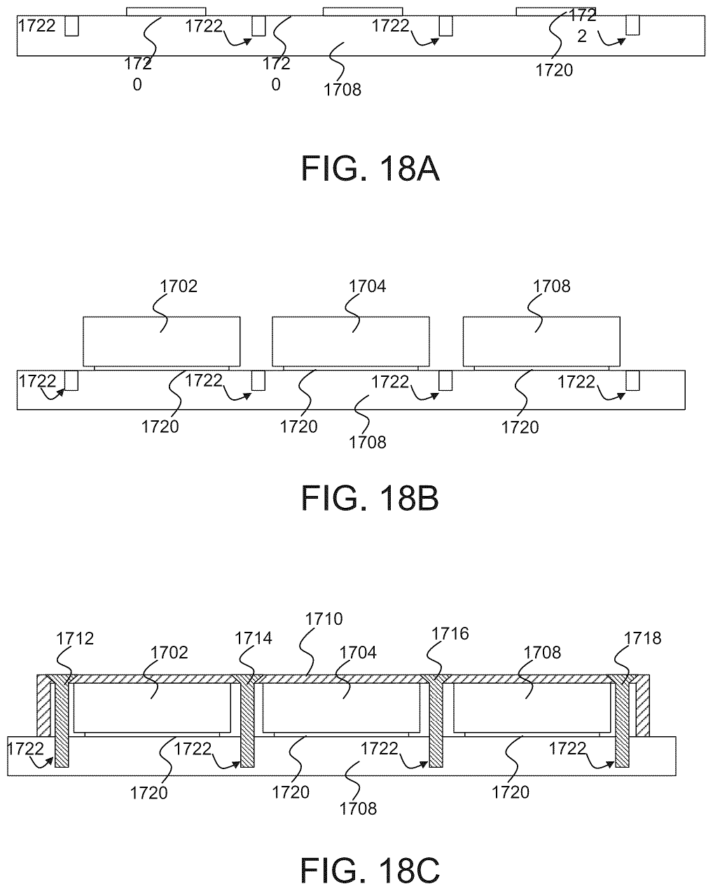

FIGS. 18A-18C set forth an example process for fabricating the system 1700 of FIG. 17. In FIG. 18A, the coupling material 1720 is deposited on the base 1708. In one example, the coupling material is a film of sinter paste (e.g., silver sinter paste). The base 1708 can include pre-formed threaded holes 1722. In FIG. 18B, the semiconductor package assemblies 1702, 1704, 1706 are disposed on the coupling material and a bonding process is carried out, such as reflow, sintering, brazing, or other processes. In FIG. 18C, the clamping tool 1710 is disposed on the semiconductor package assemblies 1702, 1704, 1706 and fastened to the base 1708 via screws 1712, 1714, 1716, 1718 that are inserted through the clamping tool 1710 and fastened into the threaded holes 1722.

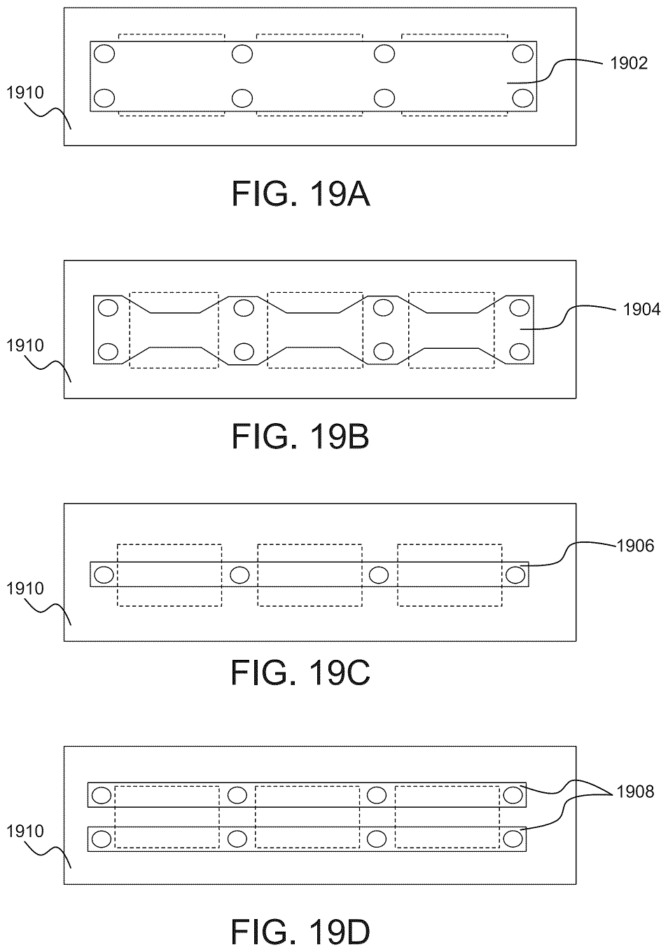

FIGS. 19A-19D set forth example implementations of the clamping tool 1710 of FIG. 17. In FIG. 19A, the clamping tool 1902 is a single piece that covers or substantially covers the semiconductor package assemblies (shown in dashed lines). The clamping tool 1902 is fastened to the base 1910. In FIG. 19B, the clamping tool 1904 is a single piece that includes tapered portions, allowing a part number or other marking on the surface of the package to be visible and/or pins to extend from the surface of the semiconductor package assembly. The clamping tool 1904 is fastened to the base 1910. In FIG. 19C, the clamping tool 1906 is a single piece that does not cover the entire surface of the package assembly. For example, the clamping tool 1906 may cover less than 75% of the respective surfaces of the packages. The clamping tool 1906 is fastened to the base 1910. This implementation also allows a part number or other marking to be visible or pins to extend. In FIG. 19D, the clamping tool 1908 includes two pieces, each covering less than 50% of the respective surfaces of the package. The clamping tool 1908 is fastened to the base 1910. This implementation also allows a part number or other marking to be visible or pins to extend.

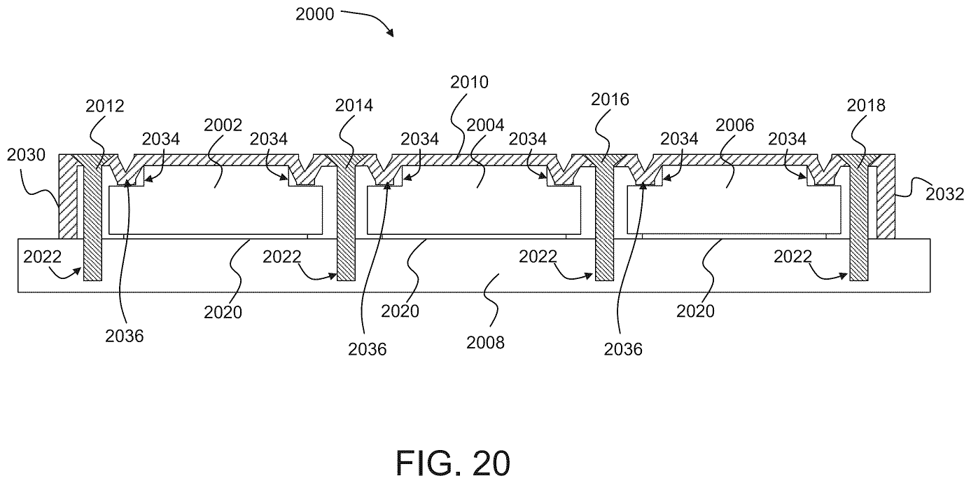

FIG. 20 sets forth another example system 200 for dual coupling of a semiconductor package assembly in accordance with at least one embodiment of the present disclosure. In the example of FIG. 20, semiconductor package assemblies 2002, 2004, 2006 are coupled to a base 1708 via coupling material 1720. For example, the coupling material 1720 can be a conductive adhesive such as solder or sinter material. In a particular implementation, the semiconductor package assemblies 2002, 2004, 2006 are sintered onto the base 2008. In some implementations, the base 2008 is a thermal dissipation appliance such as a heat sink or water jacket. The semiconductor package assemblies 2002, 2004, 2006 can implement the semiconductor package assembly 102 of FIG. 1 or 2 or the semiconductor package assembly 302 of FIG. 3, or similar devices. In a particular implementation, the semiconductor package assemblies 2002, 2004, 2006 are power modules, as discussed above.

A clamping tool 2010 is disposed across the top surfaces of the semiconductor package assemblies 2002, 2004, 2006. The clamping tool 2010 is coupled to the base 2008 by screws 2012, 2014, 2016, 2018. In some implementations, the screws 2012, 2014, 2016, 2018 are countersunk screws that are inserted through the clamping tool 2010 and fastened into a threaded hole 2022 in the base 2008. In these implementations, the clamping tool 2010 includes a conical-shaped through hole into which a conical-shaped screw head is received. This allows the top surfaces of the screws 2012, 2014, 2016, 2018 to be substantially coplanar with a top surface of the clamping tool 1710. The semiconductor package assemblies 2002, 2004, 2006 each include recesses 2034 in the surface of the semiconductor package assembly at each side. The clamping tool 2010 exerts a compressive force on semiconductor package assemblies 2002, 2004, 2006 to reduce the stress on the bond between the semiconductor package assemblies 2002, 2004, 2006 and the base 2008 caused by, for example, thermal cycling.

Support structures 2036 of the clamping tool 2010 protrude downward into the recesses 2034 of the semiconductor package assemblies 2002, 2004, 2006 and contact the surfaces in the recesses 2034. These support structures 2036 provide additional pressure points to ensure that the sides of the semiconductor package assemblies 2002, 2004, 2006 do not lift from the surface of the base 2008, which would weaken the bond between the semiconductor package assemblies 2002, 2004, 2006 and the base 2008. In some examples, the support structures are V-shaped, as shown in FIG. 20. In other examples, the support structures 2036 can be one or more pillars, a beam, and so forth. In some implementations, the clamping tool 2010 includes two or more sidewalls 2030, 2032 that extend downward toward a surface of the base 2008. The sidewall 2030, 2032 can serve to offset the clamping tool from the base 2008 and prevent over-clamping.

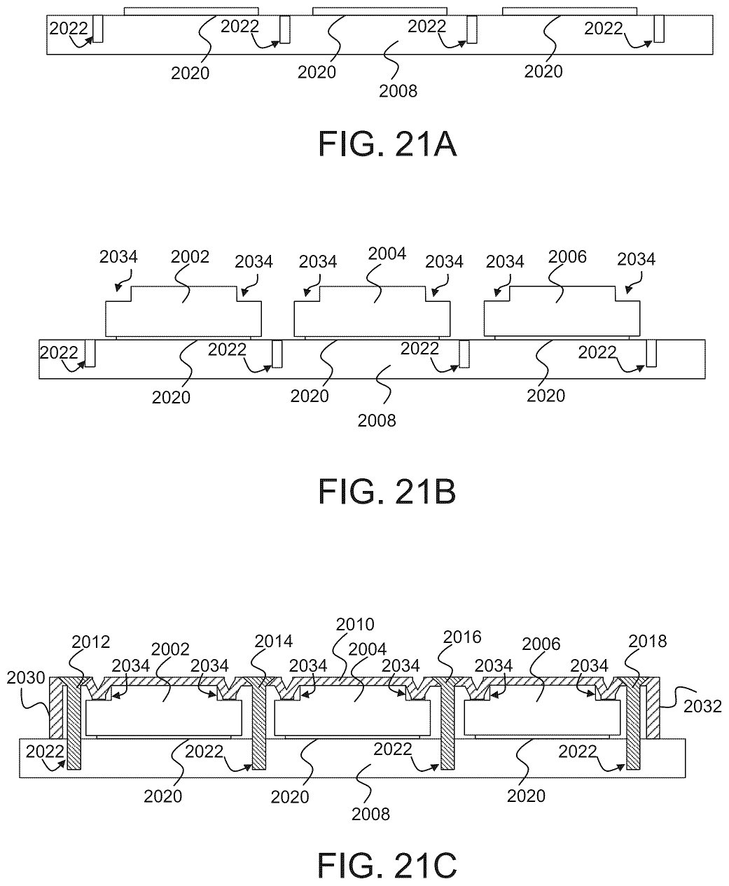

FIGS. 21A-21C set forth an example process for fabricating the system 2000 of FIG. 20. In FIG. 21A, the coupling material 2020 is deposited on the base 2008. In one example, the coupling material is a film of sinter paste (e.g., silver sinter paste). The base 1708 can include pre-formed threaded holes 2022. In FIG. 21B, the semiconductor package assemblies 2002, 2004, 2006 are disposed on the coupling material 2020 and a bonding process is carried out, such as reflow, sintering, or other processes. In FIG. 21C, the clamping tool 2010 is disposed on the semiconductor package assemblies 2002, 2004, 2006 and fastened to the base 2008 via screws 2012, 2014, 2016, 2018 that are inserted through the clamping tool 2010 and fastened into the threaded holes 2022.

Various types of layered substrates may be employed to support semiconductor devices and provide electrical insulation and thermal conduction. Such substrates can include direct bonded metal (DBM) substrates, active metal brazed (AMB) substrates, insulated metal substrates (IMS), and aluminum-based substrates. Each of these substrate types includes a plurality of layers comprising at least one conductive layer, at least one insulating layer, and at least one thermally conductive base or support layer.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, an AMB substrate can include a ceramic insulating layer to which copper layers are bonded using an active metal brazing process. The brazing process employs a braze alloy containing active elements configured to promote adhesion between the copper and the ceramic. The ceramic materials may include aluminum nitride or silicon nitride, among others.

In some implementations, an IMS can include a metal base layer, a dielectric insulating layer disposed on the metal base, and a conductive metal layer formed on the dielectric. The dielectric layer is formed of a material exhibiting both electrical insulation and thermal conductivity. The metal base layer may be formed of aluminum or other thermally conductive metals. The conductive metal layer may be copper or a copper-based alloy.

In some implementations, an aluminum-based substrate can include an aluminum support layer, a dielectric insulating layer disposed on the aluminum support layer, and a conductive circuit layer disposed on the dielectric layer. In some configurations, the aluminum support layer may also serve as a base for other composite substrate structures.

In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

As discussed above, the semiconductor package assemblies described herein can include a plurality of external terminals. The plurality of external terminals can be power terminals, input signal terminals, output signal terminals, and so forth. In some implementations, the plurality of externa terminals can be included in a lead frame. In some implementations, a lead frame can include any type of conductive portion of a package (e.g., conductive portion, conductive terminal) that can provide an external connection point from a package. Accordingly, a lead frame can be referred to as a conductive portion of a package or assembly. In some implementations, one or more portions of a lead frame can be coupled to a pad (e.g., a bond pad) on at least a portion of a DBM substrate and/or a semiconductor die.

Although referred to, by way of example, as a lead frame in at least some portions of this detailed description, the lead frame can include any type of conductive portion of a package (e.g., conductive portion, conductive terminal) that can provide an external connection point from a package. Accordingly, the lead frame can be referred to as a conductive portion of the package. In some implementations, one or more portions of a lead frame can be coupled to a pad (e.g., a bond pad) on at least a portion of a DBM substrate.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a lead frame, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, semiconductor package assemblies describe herein can include spacer material. In these implementations, a spacer material can be an epoxy, a silicone adhesive, a conductive material, a non-conductive material, an organic material, a semiconductor material, a metal alloy, a metal foam, a phase change material, etc.

It will be understood that, in the foregoing description, when an element, such as a layer, a region, or a substrate, is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application may be amended to recite exemplary relationships described in the specification or shown in the figures.

As used in this specification, a singular form may, unless definitely indicating a particular case in terms of the context, include a plural form. Spatially relative terms (e.g., over, above, upper, under, beneath, below, lower, top, bottom, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Silicon Carbide (SiC), Gallium Arsenide (GaAs), Gallium Nitride (GaN), and/or so forth.

While certain features of the described implementations have been illustrated as described herein, many modifications, substitutions, changes and equivalents will now occur to those skilled in the art. For instance, features illustrated with respect to one implementation can, where appropriate, also be included in other implementations. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

What is claimed is:

1. An apparatus comprising:
a thermal dissipation appliance;
a semiconductor package assembly bonded to the thermal dissipation appliance by a thermally conductive adhesive material; and
at least one clamping tool mechanically coupled to the semiconductor package assembly and to the thermal dissipation appliance, the at least one clamping tool exerting a compressive force on the semiconductor package assembly to maintain an interface between the semiconductor package assembly and the thermal dissipation appliance.

2. The apparatus of claim 1, wherein the at least one clamping tool includes a screw inserted through a washer, at least a portion of the washer being in contact with the semiconductor package assembly, the screw being fastened to a threaded hole in the thermal dissipation appliance.

3. The apparatus of claim 2, wherein screw is countersunk in the washer.

4. The apparatus of claim 2, wherein a portion of a particular washer is seated in a recessed portion of the semiconductor package assembly.

5. The apparatus of claim 4, wherein a top surface of the washer is substantially coplanar with a top surface of the semiconductor package assembly, the screw being countersunk in the washer.

6. The apparatus of claim 4, wherein a surface of the recessed portion includes a groove, a clamping tool including a protrusion inserted into the groove.

7. The apparatus of claim 1, wherein the at least one clamping tool includes an L-shaped member having a first end bonded to the semiconductor package assembly and a second end bonded to the thermal dissipation appliance.

8. The apparatus of claim 1, wherein the thermal dissipation appliance is a cooler having a fluid cavity connected to an inlet port and an outlet port.

9. The apparatus of claim 1, wherein the thermal dissipation appliance is a heat sink.

10. The apparatus of claim 1, wherein the semiconductor package assembly includes:
at least one semiconductor die mounted on a substrate; and
molding material, wherein a bottom surface of the substrate is exposed through the molding material, the bottom surface being bonded to the thermal dissipation appliance.

11. The apparatus of claim 10, wherein the substrate is a layered substrate including one of a direct-bonded metal substrate, an active metal brazed substrate, an aluminum substrate, and an insulated metal substrate.

12. The apparatus of claim 10, wherein the at least one semiconductor die includes a silicon carbide device die, a silicon die, and a gallium nitride die.

13. The apparatus of claim 1, wherein the semiconductor package assembly is sintered to the thermal dissipation appliance.

14. An apparatus comprising:
a thermal dissipation appliance;
a plurality of semiconductor package assemblies including at least a first semiconductor package assembly, a second semiconductor package assembly, and a third semiconductor package assembly, the plurality of semiconductor package assemblies being bonded to the thermal dissipation appliance; and
at least one clamping tool mechanically coupled to the plurality of semiconductor package assemblies and to the thermal dissipation appliance, the at least one clamping tool exerting a compressive force on the plurality of semiconductor package assemblies.

15. The apparatus of claim 14, wherein each of the plurality of semiconductor package assemblies includes at least two semiconductor power device dies receiving a direct current output and supplying a phase output of a three-phase inverter.

16. The apparatus of claim 14, wherein the at least one clamping tool includes an individual clamping tool disposed across a top surface of each of the plurality of semiconductor package assemblies and mechanically coupled to the thermal dissipation appliance.

17. The apparatus of claim 16, wherein each of the plurality of semiconductor package assemblies includes two or more recesses in a surface; and wherein a portion of the individual clamping tool is disposed in the two or more recesses.

18. The apparatus of claim 14, wherein each of the plurality of semiconductor package assemblies includes two or more recesses in a surface; wherein the at least one clamping tool includes:
a first washer is seated in a first recess of the first semiconductor package assembly, the first washer having an L-shape;
a second washer seated in a second recess of the first semiconductor package assembly and a third recess of the second semiconductor package assembly, the second washer having a flat shape;
a third washer seated in a fourth recess of the second semiconductor package assembly and a fifth recess of the third semiconductor package assembly, the third washer having a flat shape; and
a fourth washer seated in a sixth recess of the third semiconductor package assembly, the fourth washer having an L-shape;
wherein each of the first washer, the second washer, and the third washer are coupled to the thermal dissipation appliance via two or more countersunk screws.

19. The apparatus of claim 14, wherein each of the plurality of semiconductor package assemblies includes:
a layered substrate including a top metal layer, an insulating layer, and a bottom metal layer, wherein the layered substrate in one of a direct-bonded metal substrate, an active metal brazed substrate, and aluminum substrate, and an insulated metal substrate;
two or more semiconductor power device dies mounted on the top metal layer of the layered substrate; and
molding material at least partially encapsulating the layered substrate, a portion of the bottom metal layer being exposed through the molding material, wherein the portion of the bottom metal layer is sintered to a surface of the thermal dissipation appliance.

20. The apparatus of claim 19, wherein at least one of the two or more semiconductor power device dies includes a silicon carbide device die, a silicon die, and a gallium nitride die.

21. The apparatus of claim 14, wherein the at least one clamping tool includes at least one screw inserted into at least one threaded hole in the thermal dissipation appliance.

22. A method of manufacturing an assembly for dual coupling a semiconductor package assembly to a component, the method comprising:
disposing a thermally conductive adhesive on a thermal dissipation appliance;
sintering at least one semiconductor package assembly to the thermal dissipation appliance; and
coupling at least one clamping tool to the at least one semiconductor package assembly and to the thermal dissipation appliance, the at least one clamping tool exerting a compressive force on the at least one semiconductor package assembly.
